(19) United States
(12) Patent Application Publication
(10) Pub. No.: US 2013/0324722 A1
(43) Pub. Date: Dec. 5, 2013

(54) PHOSPHOR

(71) Applicant: INDUSTRIAL TECHNOLOGY RESEARCH INSTITUTE, Hsinchu (TW)

(72) Inventors: Shuang-Chao Chung, Hsinchu County (TW); Yu-Tang Li, New Taipei City (TW); Chih-Hsun Fan, Hsinchu City (TW); Ming-Chia Li, Taichung City (TW); Chang-Sheng Chu, Hsinchu City (TW)

(73) Assignee: Industrial Technology Research Institute, Hsinchu (TW)

(21) Appl. No.: 13/854,156

(22) Filed: Apr. 1, 2013

Related U.S. Application Data
(60) Provisional application No. 61/653,400, filed on May 30, 2012.

(30) Foreign Application Priority Data
Dec. 24, 2012 (TW) 101149594

(51) Int. Cl. H01L 33/50

(52) U.S. Cl. CPC H01L 33/502
USPC 544/231; 544/319

(57) ABSTRACT

A phosphor is provided, which has a chemical structure represented by General Formula I:

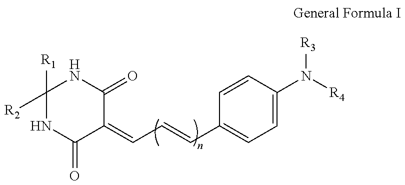

wherein n is an integer; R₁ and R₂ are respectively selected from the group consisting of an alkyl group, an aryl group and a heterocyclic group, or R₁ and R₂ are linked to each other, together with a carbon atom to which R₁ and R₂ are bonded, to form a ring structure; R₃ and R₄ are respectively selected from the group consisting of a hydrogen atom, a C₁-C₄ alkyl group, a C₁-C₄ alkoxyl group, a carboxyl group, a C₁-C₄ alkyl ester group, a arylester group, an adamantyl carbonyl group and an adamantyl group, or R₃ and R₄ are linked to each other, together with a nitrogen atom to which R₃ and R₄ are bonded, to form a nitrogen-containing heterocyclic group.

### CROSS-REFERENCE TO RELATED APPLICATION

This application claims the priority benefits of U.S. provisional application Ser. No. 61/653,400, filed on May 30, 2012 and Taiwan application serial no. 101149594, filed on Dec. 24, 2012. The entirety of each of the above-mentioned patent applications is hereby incorporated by reference herein and made a part of this specification.

### TECHNICAL FIELD

The technical field relates to a phosphor.

### BACKGROUND

Besides the properties of high photoelectric conversion efficiency and long service life, light-emitting diodes (LEDs) also have the characteristic of being capable of modulating the light intensity in real time.

Presently, the technology adopted to modulate the light intensity in the conventional manner is adopting chips of the three primary colors, namely, red, blue and green, to present different illumination colors. However, the manner of adopting the three primary colors to modulate colors may cause metamerism (that is, the same color may have different spectrum distributions); and furthermore, since the presented spectrums are non-continuous, the color rendering index cannot exceed 90, so that true colors cannot be completely presented. Therefore, it is an important issue to enable an LED to have the characteristic of modulating the spectrum while presenting true colors.

### SUMMARY

The disclosure provides a phosphor, having a chemical structure represented by General Formula I:

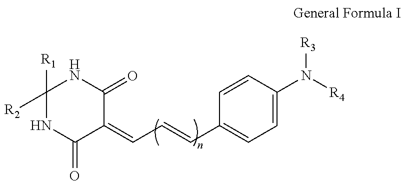

in which n is an integer; R₁ and R₂ are respectively selected from the group consisting of a substituted or unsubstituted alkyl group, a substituted or unsubstituted aryl group and a substituted or unsubstituted heterocyclic group, or R₁ and R₂ are linked to each other, together with a carbon atom to which R₁ and R₂ are bonded, to form a ring structure; R₃ and R₄ are respectively selected from the group consisting of a hydrogen atom, a substituted or unsubstituted C₁-C₄ alkyl group, a substituted or unsubstituted C₁-C₄ alkoxyl group, a carboxyl group, a substituted or unsubstituted C₁-C₄ alkyl ester group, a substituted or unsubstituted arylester group, an adamantyl carbonyl group and an adamantyl group, or R₃ and R₄ are linked to each other, together with a nitrogen atom to which R₃ and R₄ are bonded, to form a nitrogen-containing heterocyclic group.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1A to FIG. 1D are schematic cross-sectional views of four LED package structures according to an embodiment of the disclosure.

### DETAILED DESCRIPTION OF DISCLOSED EMBODIMENTS

The term “alkyl group” used herein refers to a branched or straight fully saturated acyclic aliphatic hydrocarbon group (i.e. composed of carbon atoms and hydrogen atoms containing no double bond or triple bond). The alkyl group includes methyl, ethyl, propyl, isopropyl, butyl, isobutyl, tert-butyl, pentyl, hexyl and the like, but the disclosure is not limited thereto.

The term “aryl group” used herein refers to a homocyclic aromatic radical having a single ring or multiple fused rings. The aryl group includes phenyl, naphthyl, phenanthryl, naphthacenyl, fluorenyl, pyrenyl and the like, but the disclosure is not limited thereto.

The term “C₁-C₄ alkyl group” used herein refers to an alkyl group having 1 to 4 carbon atoms.

The term “C₁-C₄ alkoxyl group” used herein refers to an alkyl radical having 1 to 4 carbon atoms that are covalently bonded to the parent molecule through a —O— linkage. The C₁-C₄ alkoxyl group includes methoxy, ethoxy, propoxy, isopropoxy, butoxy, n-butoxy, sec-butoxy, tert-butoxy and the like, but the disclosure is not limited thereto.

The term “carboxyl group” used herein refers to —C(═O)OH.

The term “C₁-C₄ alkyl ester group” used herein refers to —C(═O)OR, in which R is an alkyl group having 1 to 4 carbon atoms.

The term “arylester” used herein refers to —C(═O)OPh, in which Ph is phenyl.

Herein, a group may represent a substituted or unsubstituted group, otherwise it is specifically stated whether the group is substituted. For example, a “alkyl group” may represent a substituted or unsubstituted alkyl group.

The disclosure provides a phosphor, having a chemical structure represented by General Formula I:

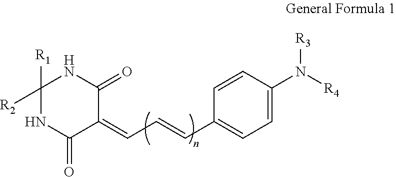

in which n is an integer of 0 or 1; R₁ and R₂ are respectively selected from the group consisting of a substituted or unsubstituted alkyl group, a substituted or unsubstituted aryl group and a substituted or unsubstituted heterocyclic group, or R₁ and R₂ are linked to each other, together with a carbon atom to which R₁ and R₂ are bonded, to form a ring structure; R₃ and R₄ are respectively selected from the group consisting of a hydrogen atom, a substituted or unsubstituted C₁-C₄ alkyl group, a substituted or unsubstituted C₁-C₄ alkoxyl group, a carboxyl group, a substituted or unsubstituted C₁-C₄ alkyl ester group, a substituted or unsubstituted arylester group, an adamantyl carbonyl group and an adamantyl group, or R₃ and R₄ are linked to each other, together with a nitrogen atom to which R₃ and R₄ are bonded, to form a nitrogen-containing heterocyclic group.

In an embodiment, R₁ and R₂ may be linked to each other, together with a carbon atom to which R₁ and R₂ are bonded, to form an adamantyl group, bicyclo[2,2,1]heptanyl, cyclohexyl or cyclodecyl.

In General Formula I, when R₁ and R₂ are linked to each other, together with a carbon atom to which R₁ and R₂ are bonded, to form an adamantyl group, R₃ may be methyl or ethyl, and R₄ may be ethyl or hydroxymethyl. In an embodiment, the phosphor is, for example,

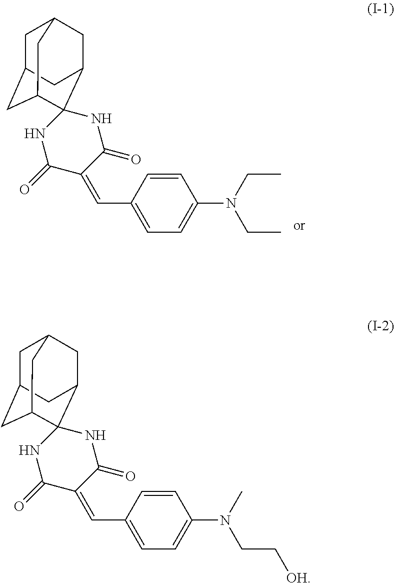

In General Formula I, when R₁ and R₂ are linked to each other, together with a carbon atom to which R₁ and R₂ are bonded, to form bicyclo[2,2,1]heptanyl, R₃ may be ethyl, and R₄ may be ethyl. In an embodiment, the phosphor is, for example,

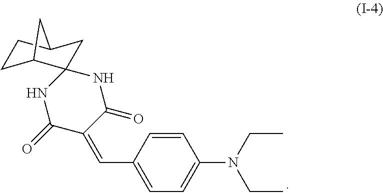

In General Formula I, when R₁ and R₂ are linked to each other, together with a carbon atom to which R₁ and R₂ are bonded, to form cyclohexyl, R₃ may be ethyl, and R₄ may be ethyl. In an embodiment, the phosphor is, for example,

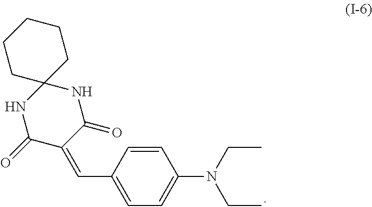

In General Formula I, when R₁ and R₂ are linked to each other, together with a carbon atom to which R₁ and R₂ are bonded, to form cyclodecyl, R₃ may be ethyl, and R₄ may be ethyl. In an embodiment, the phosphor is, for example,

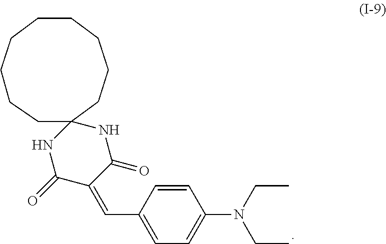

In General Formula I, when R₁ is methyl and R₂ is ethyl, R₃ may be ethyl, and R₄ may be ethyl. In an embodiment, the phosphor is, for example,

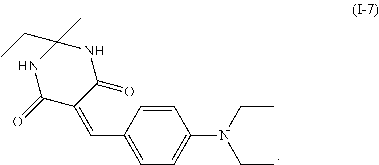

In General Formula I, when R₁ is methyl and R₂ is phenyl, R₃ may be a hydrogen atom or methyl, and R₄ may be a hydrogen atom or methyl. In an embodiment, the phosphor is, for example,

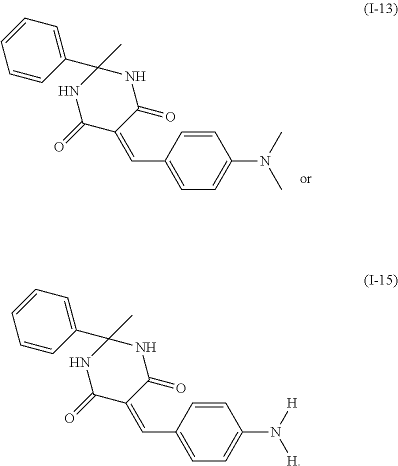

In General Formula I, when R₁ is methyl and R₂ is methyl, R₃ may be methyl, ethyl, butyl or cyanomethyl, and R₄ may be methyl, ethyl, butyl or cyanomethyl, or R₃ and R₄ are linked to each other, together with a nitrogen atom to which R₃ and R₄ are bonded, to form a nitrogen-containing heterocyclic group. In an embodiment, the phosphor is, for example,

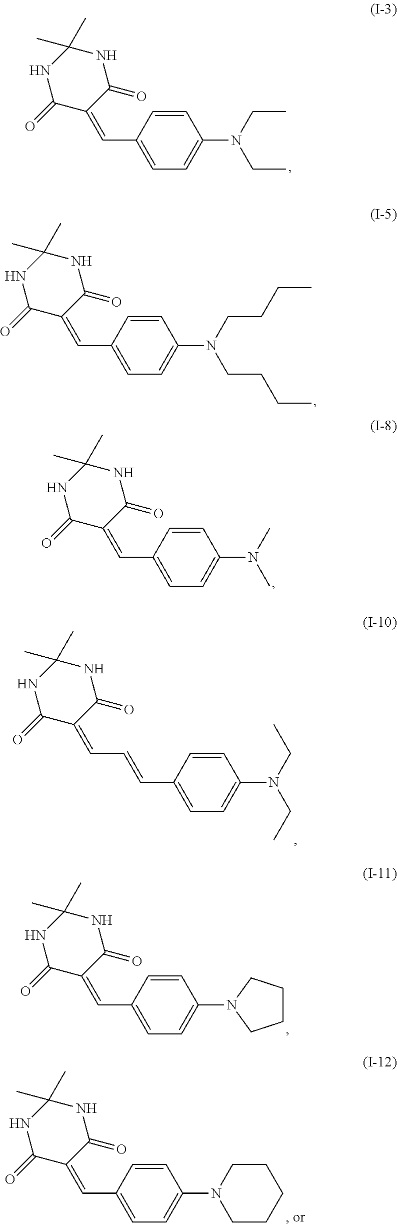 [SMILES: CCN(CC)c1ccc(C=C2C(=O)NC(C)(C)NC2=O)cc1 ; CCCCN(CCCC)c1ccc(C=C2C(=O)NC(C)(C)NC2=O)cc1 ; CN(C)c1ccc(C=C2C(=O)NC(C)(C)NC2=O)cc1 ; CCN(CC)c1ccc(/C=C/C=C2C(=O)NC(C)(C)NC2=O)cc1 ; CC1(C)NC(=O)C(=Cc2ccc(N3CCCC3)cc2)C(=O)N1 ; CC1(C)NC(=O)C(=Cc2ccc(N3CCCCC3)cc2)C(=O)N1]

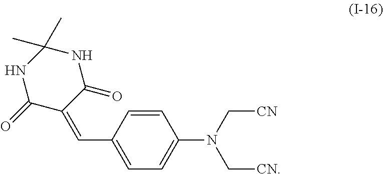 [SMILES: CC1(C)NC(=O)C(=Cc2ccc(N(CC#N)CC#N)cc2)C(=O)N1]

In an embodiment, R₃ may be methyl, and R₄ may be methyl.

In an embodiment, R₃ may be ethyl, and R₄ may be ethyl.

In an embodiment, R₃ may be butyl, and R₄ may be butyl.

In an embodiment, R₃ may be methyl, and R₄ may be hydroxyethyl.

In an embodiment, R₃ may be a hydrogen atom, and R₄ may be a hydrogen atom.

In an embodiment, R₃ may be cyanomethyl, and R₄ may be cyanomethyl.

In an embodiment, R₃ and R₄ are linked to each other, together with a nitrogen atom to which R₃ and R₄ are bonded, to form a nitrogen-containing heterocyclic group, in which the nitrogen-containing heterocyclic group may be pyrrolidinyl or piperidyl.

It should be noted that, the phosphor of the disclosure can be used as a light source with different band spectrums, bandwidths and luminances, in combination with LEDs of different wavelength in different manners, and can be applied to sunlight-simulating light sources or flash light-simulating light sources according to different actual demands.

The disclosure is clearly and completely disclosed below by exemplifying specific experimental examples. However, the disclosure is not limited to the disclosed experimental examples.

### Experimental Example

Compound (I-1) to Compound (I-13) and Compound (I-15) and Compound (I-16) represented by General Formula I and mentioned in the embodiments can be obtained through steps and conditions shown in the Formula 2 below.

First, Step 1 is performed. At room temperature, 0.01 mole of Compound (1), 0.01 mole of malonamide are added to an aqueous solution containing 98 wt % sulfuric acid, and a dehydrate reaction is carried out for 8 hrs in the presence of sulfuric acid, to obtain Compound (2).

Next, Step 2 is performed. 0.005 mole of Compound (2) and 0.005 mole of Compound (3) are refluxed for 8 hrs with 10 mL of methanol as a solvent, to obtain General Formula I.

### Step 1

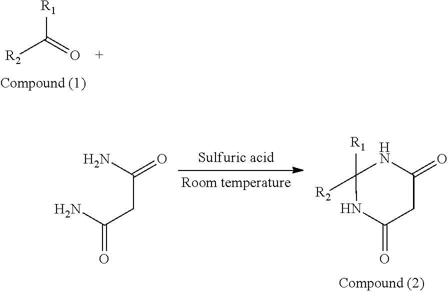

### Step 2

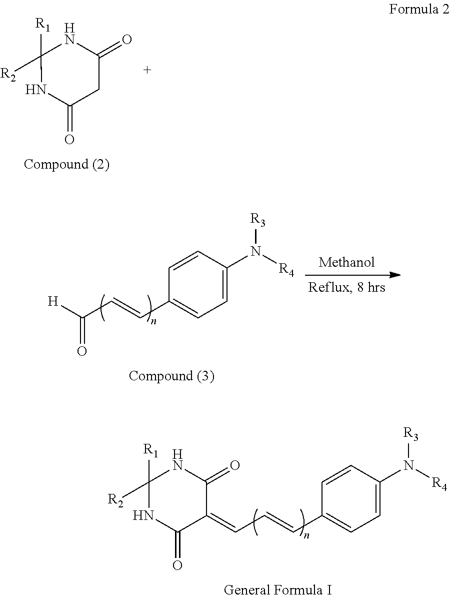

The definitions of n, R₁, R₂, R₃ and R₄ in Formula 2 are the same as those of n, R₁, R₂, R₃ and R₄ in General Formula I.

### Evaluation of Optical Properties

The above prepared Compound (I-1) to Compound (I-13) and Compound (I-15) to Compound (I-16) are dissolved in methanol, and formulated, to obtain a dilute solution. Then, the maximum absorption wavelength and the fluorescence emitting wavelength are respectively measured by using instruments: JASCO-815 and Hitachi FL2500, and the obtained data are shown in Table 1 below.

TABLE 1

| Compound | Maximum Absorption | Fluorescence Emitting |
|---|---|---|
| No. | Wavelength (MeOH) | Wavelength (MeOH) |
| (I-1) | 434 mn | 505 nm |
| (I-2) | 429 nm | 509 nm |
| (I-3) | 430 nm | 502 nm |
| (I-9) | 431 nm | 525 nm |
| (I-16) | 434 nm | 500 nm |

It can be known from Table 1 that, the maximum absorption wavelengths of Compound (I-1), Compound (I-2), Compound (I-3), Compound (I-9) and Compound (I-16) are in the range of about 429 to 434 nm, and the fluorescence emitting wavelengths are in the range of about 500 to 525 nm. Therefore, it can be known from the data that, the phosphor of the disclosure can absorb blue light and emit yellow light.

### Type of LED Package

Due to the characteristic of being capable of absorbing blue light and emitting yellow light, the above prepared Compound (I-1) to Compound (I-13) and Compound (I-15) to Compound (I-16) can be applied to an LED package structure.

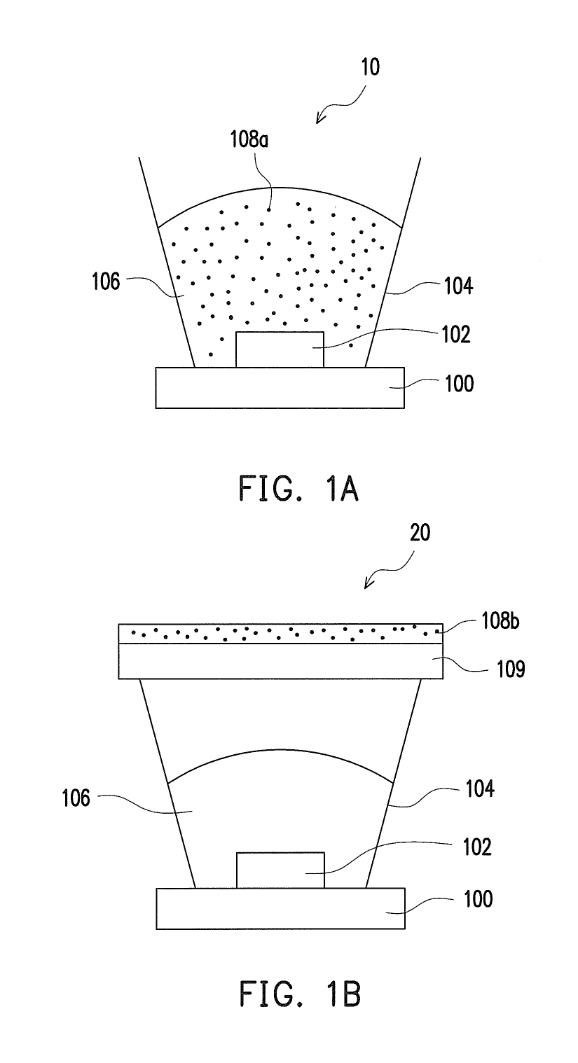

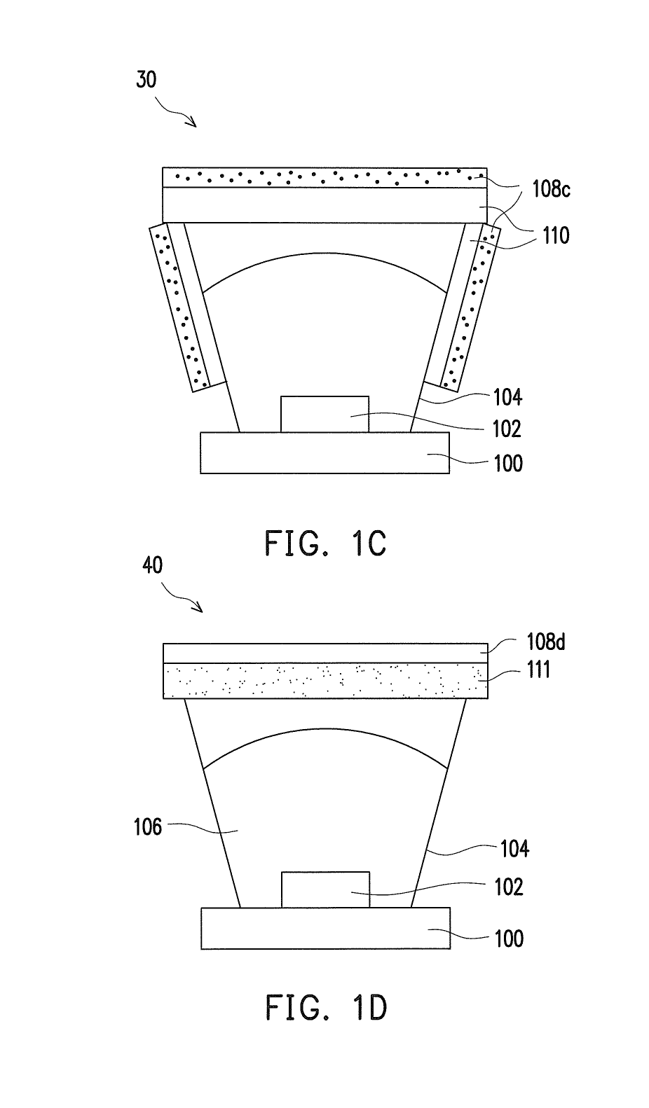

FIG. 1A to FIG. 1D are schematic cross-sectional views of four LED package structures according to an embodiment of the disclosure.

First, referring to FIG. 1A, an LED package structure 10 includes a circuit board 100, an LED chip 102, a reflector 104, a package colloid 106 and a phosphor 108a, wherein the circuit board 100 has a heat dissipation function, the phosphor 108a includes at least one of Compound (I-1) to Compound (I-13) and Compound (I-15) to Compound (I-16) mentioned above.

Specifically, a preparation method of the phosphor 108a is as follows. At least one of Compound (I-1) to Compound (I-13) and Compound (I-15) to Compound (I-16) is added to a methanol solution containing 10 wt % poly(vinylpyrrolidone) (PVP), and formulated, to obtain a fluorescent solution having a fluorescent dye content of 0.05 wt %; next, the solution is uniformly mixed with the package colloid 106, to fabricate the LED package structure 10 shown in FIG. 1A that can convert light emitted by the LED chip 102 through the phosphor 108a.

Next, referring to FIG. 1B, an LED package structure 20 in FIG. 1B is similar to the LED package structure 10 in FIG. 1A, and the difference merely lies in that the LED package structure 20 further includes a transparent carrier board 109 that is disposed above the package colloid 106 and covers the opening of the reflector 104, and a phosphor 108b is formed by coating the fluorescent solution on the transparent carrier board 109.

Then, referring to FIG. 1C, an LED package structure 30 in FIG. 1C is similar to the LED package structure 20 in FIG. 1B, and the difference merely lies in that a transparent carrier board 110 of the LED package structure 30 not only covers the opening of the reflector 104, but also is disposed on a side wall of the reflector 104, and a phosphor 108c is formed by coating the fluorescent solution on the transparent carrier board 110.

Then, referring to FIG. 1D, an LED package structure 40 in FIG. 1D is similar to the LED package structure 10 in FIG. 1A, and the difference merely lies in that the LED package structure 40 further includes a diffuser plate 111 that is disposed above the package colloid 106 and covers the opening of the reflector 104, and a phosphor 108d is formed by coating the fluorescent solution on the diffuser plate 111.

However, persons of ordinary skill in the art should understand that, the application of the LED package is not limited to the LED package structures 10, 20, 30 and 40 mentioned above, and may also be applied to LED package structures of other types according to actual demands.

In view of the above, the phosphor of the embodiments is a novel organic phosphor, and can be used as light sources with different band spectrums, bandwidths and luminances, in combination with existing LEDs, so that the restriction of the LED color could be improved. Further, the phosphor of the embodiments can be effectively applied to sunlight-simulating light sources or flash light-simulating light sources.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A phosphor, having a chemical structure represented by General Formula I: 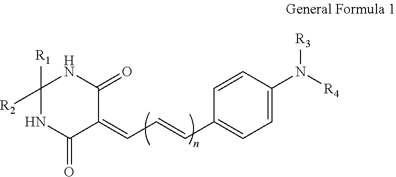
wherein n is an integer;
R₁ and R₂ are respectively selected from the group consisting of a substituted or unsubstituted alkyl group, a substituted or unsubstituted aryl group and a substituted or unsubstituted heterocyclic group, or R₁ and R₂ are linked to each other, together with a carbon atom to which R₁ and R₂ are bonded, to form a ring structure;
R₃ and R₄ are respectively selected from the group consisting of a hydrogen atom, a substituted or unsubstituted C₁-C₄ alkyl group, a substituted or unsubstituted C₁-C₄ alkoxyl group, a carboxyl group, a substituted or unsubstituted C₁-C₄ alkyl ester group, a substituted or unsubstituted arylester group, an adamantyl carbonyl group and an adamantyl group, or R₃ and R₄ are linked to each other, together with a nitrogen atom to which R₃ and R₄ are bonded, to form a nitrogen-containing heterocyclic group.

2. The phosphor according to claim 1, wherein the ring structure comprises an adamantyl group, bicyclo[2,2,1]heptanyl, cyclohexyl and cyclodecyl.

3. The phosphor according to claim 2, wherein when the ring structure is an adamantyl group, R₃ is methyl or ethyl, and R₄ is ethyl or hydroxyethyl.

4. The phosphor according to claim 3, comprising:

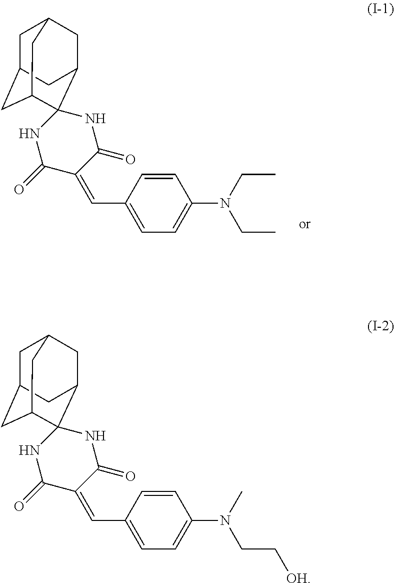 [SMILES: CCN(CC)c1ccc(C=C2C(=O)NC3(NC2=O)C2CC4CC(C2)CC3C4)cc1 ; CN(CCO)c1ccc(C=C2C(=O)NC3(NC2=O)C2CC4CC(C2)CC3C4)cc1]

5. The phosphor according to claim 2, wherein when the ring structure is bicyclo[2,2,1]heptanyl, R₃ is ethyl, and R₄ is ethyl.

6. The phosphor according to claim 5, comprising:

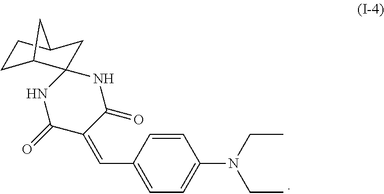 [SMILES: CCN(CC)c1ccc(C=C2C(=O)NC3(CC4CCC3C4)NC2=O)cc1]

7. The phosphor according to claim 2, wherein when the ring structure is cyclohexyl, R₃ is ethyl, and R₄ is ethyl.

8. The phosphor according to claim 7, comprising:

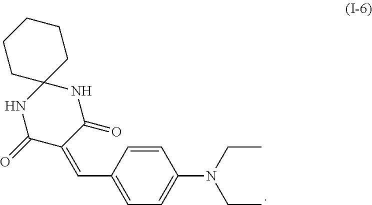 [SMILES: CCN(CC)c1ccc(C=C2C(=O)NC3(CCCCC3)NC2=O)cc1]

9. The phosphor according to claim 2, wherein when the ring structure is cyclodecyl, R₃ is ethyl, and R₄ is ethyl.

10. The phosphor according to claim 9, comprising:

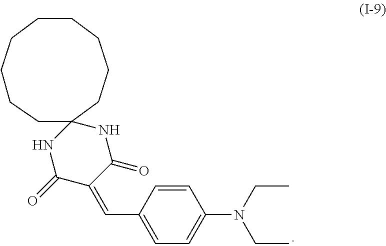 [SMILES: CCN(CC)c1ccc(C=C2C(=O)NC3(CCCCCCCCC3)NC2=O)cc1]

11. The phosphor according to claim 1, wherein when R₁ is methyl and R₂ is ethyl, R₃ is ethyl, and R₄ is ethyl.

12. The phosphor according to claim 11, comprising:

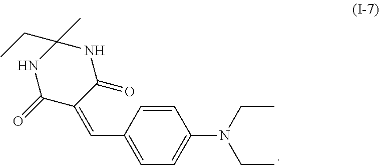 [SMILES: CCN(CC)c1ccc(C=C2C(=O)NC(C)(CC)NC2=O)cc1]

13. The phosphor according to claim 1, wherein when R₁ is methyl and R₂ is phenyl, R₃ is a hydrogen atom or methyl, and R₄ is a hydrogen atom or methyl.

14. The phosphor according to claim 13, comprising:

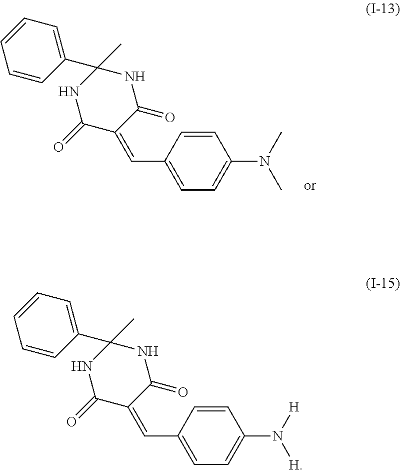

15. The phosphor according to claim 1, wherein when R₁ is methyl and R₂ is methyl, R₃ is methyl, ethyl, butyl or cyanomethyl, and R₄ is methyl, ethyl, butyl or cyanomethyl, or R₃ and R₄ are linked to each other, together with a nitrogen atom to which R₃ and R₄ are bonded, to form the nitrogen-containing heterocyclic group.

16. The phosphor according to claim 15, comprising:

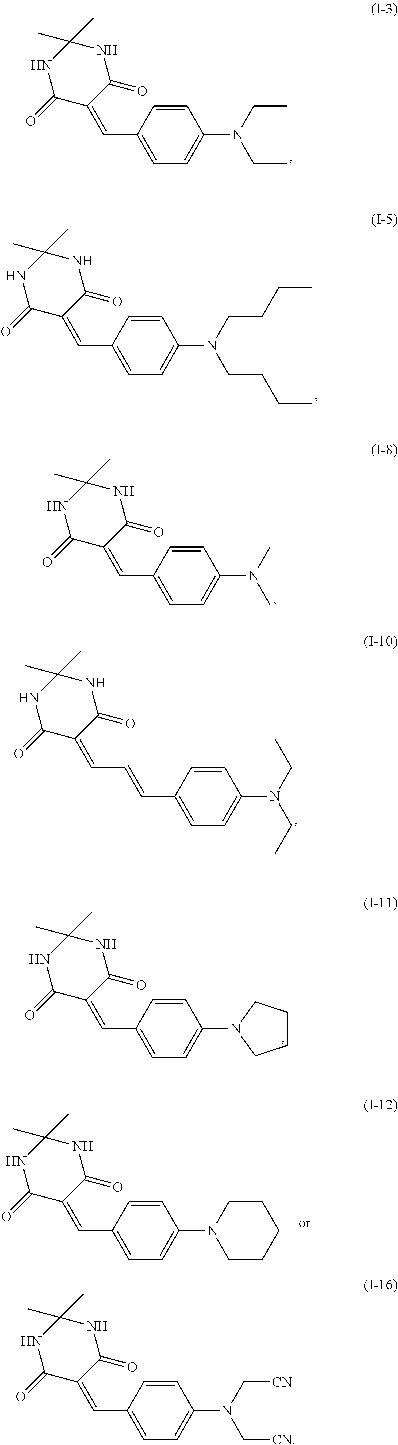

17. The phosphor according to claim 1, wherein the nitrogen-containing heterocyclic group comprises pyrrolidinyl or piperidyl.

18. The phosphor according to claim 1, wherein R₃ is methyl, and R₄ is methyl.

19. The phosphor according to claim 1, wherein R₃ is ethyl, and R₄ is ethyl.

20. The phosphor according to claim 1, wherein R₃ is butyl, and R₄ is butyl.

21. The phosphor according to claim 1, wherein R₃ is methyl, and R₄ is hydroxyethyl.

22. The phosphor according to claim 1, wherein R₃ is a hydrogen atom, and R₄ is a hydrogen atom.

23. The phosphor according to claim 1, wherein R₃ is cyanomethyl, and R₄ is cyanomethyl.

24. The phosphor according to claim 1, wherein R₃ and R₄ are linked to each other, together with a nitrogen atom to which R₃ and R₄ are bonded, to form the nitrogen-containing heterocyclic group.
